(19) United States
(12) Patent Application Publication
(10) Pub. No.: US 2018/0321560 A1
(43) Pub. Date: Nov. 8, 2018

(54) LIQUID CRYSTAL DISPLAY DEVICE AND METHOD FOR PRODUCING SAME

(71) Applicant: SHARP KABUSHIKI KAISHA, Sakai City, Osaka (JP)

(72) Inventors: Youhei NAKANISHI, Sakai City (JP); Masanobu MIZUSAKI, Sakai City (JP)

(21) Appl. No.: 15/763,588

(22) PCT Filed: Sep. 23, 2016
(86) PCT No.: PCT/JP2016/077922

§ 371 Date: Mar. 27, 2018

(30) Foreign Application Priority Data
Sep. 29, 2015 (JP) 2015-192148

(51) Int. Cl. G02F 1/1337; G02F 1/1335; G02F 1/1339; G02F 1/1362; G02F 1/1368; H01L 27/12; G02F 1/1343

(52) U.S. Cl. CPC G02F 1/133711; G02F 1/133514; G02F 1/1339; G02F 1/136286; G02F 1/1368; G02F 2001/133519; G02F 1/134363; G02F 1/133512; G02F 2201/121; G02F 2201/123; G02F 2001/134372; H01L 27/1214

(57) ABSTRACT

A liquid crystal display device includes: upper and lower substrates; a liquid crystal layer and a sealing material between the upper and lower substrates, the liquid crystal layer containing liquid crystal molecules and the sealing material sealing the liquid crystal layer; and alignment control layers for controlling alignment of the liquid crystal molecules, one between the upper substrate and the liquid crystal layer and one between the lower substrate and the liquid crystal layer, wherein the upper and lower substrates are in direct contact with the sealing material, the alignment control layers contain a polymer having a structure derived from a polarized light-absorbing monomer having a polarized light-absorbing skeleton and at least two reactive functional groups, and the polarized light-absorbing skeleton includes a cinnamoyl skeleton.

### TECHNICAL FIELD

The present invention relates to liquid crystal display devices and methods for producing a liquid crystal display device.

### BACKGROUND ART

Thin display devices such as liquid crystal display devices have spread rapidly, and are widely employed not only for televisions but also for devices such as electronic readers, digital photo frames, industrial appliances, personal computers (PCs), tablet PCs, and smartphones. Such uses require various functions, and various liquid crystal display modes have been developed.

The liquid crystal display modes include a mode in which liquid crystal molecules are aligned in a direction substantially parallel to the main surfaces of the substrates when no voltage is applied (hereinafter also referred to as the “horizontal alignment mode”). Examples thereof include an in-plane switching (IPS) mode and a fringe field switching (FFS) mode. The liquid crystal display modes also include a mode in which liquid crystal molecules are aligned in a direction substantially perpendicular to the main surfaces of the substrates when no voltage is applied (hereinafter also referred to as the “vertical alignment mode”). Examples thereof include a vertical alignment (VA) mode. In order to achieve such alignment control of liquid crystal molecules, Patent Literature 1, for example, discloses a liquid crystal display mode utilizing alignment films. Meanwhile, Patent Literatures 2 and 3 each disclose a liquid crystal display mode utilizing a technique alternative to conventional alignment films.

### CITATION LIST

### Patent Literature

Patent Literature 1: US 2012/0021141 A1

Patent Literature 2: JP 5154945 B

Patent Literature 3: JP 2010-33093 A

### SUMMARY OF INVENTION

### Technical Problem

According to Patent Literature 1, in order to stabilize the alignment for a long period of time in the IPS mode, a multifunctional monomer is added to an alignment film material to form alignment films and then the monomer is polymerized to form a polymer. The method disclosed in Patent Literature 1, however, includes a step of forming the alignment films, and particularly when the method is applied to a liquid crystal panel with a narrow frame, portions where the alignment films adhere to the sealing material are formed due to the precision level of alignment film forming devices. Thus, unfortunately, peeling of the sealing material from the alignment films occurs at the interface between the alignment films and the sealing material.

A typical liquid crystal panel utilizing conventional alignment films is described below with reference to FIG. 9. FIG. 9 is a schematic cross-sectional view illustrating a conventional typical liquid crystal panel. As illustrated in FIG. 9, a liquid crystal panel 700 includes a lower substrate 710, an upper substrate 720 facing the lower substrate 710, a liquid crystal layer 730 disposed between the substrates, and a sealing material S. The sealing material S bonds the lower substrate 710 and the upper substrate 720 together. The sealing material S also functions to hold liquid crystal sandwiched between glass substrates inside the panel. The lower substrate 710 and the upper substrate 720 respectively include alignment films 717 and 727 on liquid crystal layer sides of respective glass substrates 711 and 721. The alignment films 717 and 727 align liquid crystal molecules in a predetermined direction.

The alignment film 717 is sandwiched between the glass substrate 711 of the lower substrate 710 and the sealing material S. The alignment film 727 is sandwiched between the glass substrate 721 of the upper substrate 720 and the sealing material S. Usually, the lower substrate 710 and the upper substrate 720 include supporting substrates such as the glass substrates 711 and 721, respectively. Components such as various electrodes, an insulating film, and a color filter layer are suitably disposed on these supporting substrates, according to the liquid crystal display mode. For example, FIG. 9 illustrates the upper substrate 720 having a color filter layer CF, but other components are not shown. The conventional alignment films 717 and 727 are usually formed by polymerizing a polymerizable monomer contained in an alignment film material. Examples of such films include alignment films formed of a polymer such as polyimide.

Unfortunately, in such a conventional typical liquid crystal panel in which the alignment film 717 is sandwiched between the glass substrate 711 and the sealing material S and the alignment film 727 is sandwiched between the glass substrate 721 and the sealing material S, the sealing material may be peeled from the alignment films under stress such as external force, temperature, or humidity. Recent liquid crystal panels with narrow frames (narrowing of a frame region Rf illustrated in FIG. 9) are more susceptible to such peeling. This is because the adhesion strength between the alignment films and the sealing material is low to begin with, and decreasing the width (thickness) of the sealing material along with the design trend of the narrow frame further reduces the adhesion area between the alignment films and the sealing material, resulting in even lower adhesion strength. In addition, when the alignment films are disposed to extend to the edge of the liquid crystal panel and are in contact with an external environment, for example, moisture outside the liquid crystal panel can easily enter the liquid crystal panel through the alignment films, making the liquid crystal panel susceptible to display defects. As a structure to solve such a problem, as illustrated in FIG. 10, in a liquid crystal display device having a lower substrate 810, an upper substrate 820 facing the lower substrate 810, and a liquid crystal layer 830 disposed between the substrates, an alignment film 817 is not disposed between a glass substrate 811 and the sealing material S, and an alignment film 827 is also not disposed between a glass substrate 821 and the sealing material S so as to prevent the alignment films 817 and 827 from adhering to the sealing material S. Yet, in the case of controlling the position of the alignment films in this manner in a liquid crystal panel with a narrow frame, since the level of film forming precision of alignment film forming (printing) devices is not sufficient at the present, portions where alignment films 917 and 927 adhere to the sealing material S may be formed in a liquid crystal display device including a lower substrate 910 having a glass substrate 911, an upper substrate 920 having a glass substrate 921, and a liquid crystal layer 930 disposed between the substrates (e.g., FIG. 11).

Due to these reasons, liquid crystal panels with narrow frames cause a decrease in adhesion strength of the sealing material to the upper substrate and the lower substrate, making it difficult to prevent entrance of moisture from the outside environment into the liquid crystal panel.

In this regard, when a means alternative to conventional alignment films is employed as in the disclosures of Patent Literatures 2 and 3 described above, the peeling problem at the interface between the alignment films and the sealing material can be avoided because conventional alignment films are not used. In this case, however, only one of the horizontal alignment mode and the vertical alignment mode can be achieved.

Patent Literature 2 discloses a method for producing vertically aligned liquid crystal films on plastic substrates without using conventional alignment films. The method disclosed in Patent Literature 2, however, is intended to achieve a vertical alignment mode, and cannot achieve a horizontal alignment mode liquid crystal display device. In addition, the disclosure of Patent Literature 2 is intended for liquid crystal films, and all the liquid crystal compounds are monomers. Thus, after the liquid crystal films are produced, these the liquid crystal compounds cannot be driven by application of voltage, and thus the films cannot be used for liquid crystal displays.

According to the disclosure of Patent Literature 3, conventional alignment films are not employed, and a vertical alignment polymer layer is formed by polymerizing a polymerizable monomer having a vertical alignment group, which is added to a liquid crystal layer. The disclosure of Patent Literature 3, however, is intended to achieve a vertical alignment mode liquid crystal display device, and cannot achieve a horizontal alignment mode liquid crystal display device.

The present invention is made in view of the present situation, and aims to provide a liquid crystal display device in which the sealing material is not easily peeled from the upper and lower substrates even when the device has a narrow frame (in particular, a horizontal alignment mode liquid crystal display device). The present invention also aims to provide a method for producing the liquid crystal display device.

### Solution to Problem

The present inventors extensively studied methods that can prevent the sealing material from being easily peeled from the upper and lower substrates even in liquid crystal display devices with narrow frames and that can be applied not only to vertical alignment mode liquid crystal display devices but also to horizontal alignment mode liquid crystal display devices. As a result, they found that with a method in which a polarized light-absorbing monomer added to a liquid crystal layer is polymerized by irradiating the monomer with polarized ultraviolet light, it is possible to provide a liquid crystal display device including upper and lower substrates, and a liquid crystal layer and a sealing material disposed between the upper and lower substrates, wherein a polymer layer is formed on the liquid crystal layer-side surface of each of the upper and lower substrates. They also found that these polymer layers when imparted with ability to control alignment can be used as alternatives to conventional alignment films. With the above structure, the alignment control layers are not sandwiched between the substrates and the sealing material, so that the peeling problem described above in liquid crystal display devices can be avoided. The above structure can also reduce the entrance of moisture from the outside environment and suppress the occurrence of display defects. As a result of further keen examinations on these alignment control layers, the present inventors found that the polarized light-absorbing monomer designed to have a polarized light-absorbing skeleton containing a cinnamoyl group and at least two reactive functional groups is highly soluble in the liquid crystal layer and is easily phase-separable, which are conditions necessary for the polarized light-absorbing monomer but difficult to achieve simultaneously. In addition, polymerization of the multifunctional polarized light-absorbing monomer results in the formation of a polymer having a network structure, making it possible to form stable alignment control layers that do not easily dissolve in the liquid crystal and that are not easily deformed by an external shock. Further, the alignment control layers are applicable to both of the two modes, the horizontal alignment mode and the vertical alignment mode, in which the required pre-tilt angle is greatly different therebetween. Thus, the present inventors successfully solved the above problems and arrived at the present invention.

Specifically, according to one aspect, the present invention may relate to a liquid crystal display device including: upper and lower substrates; a liquid crystal layer and a sealing material between the upper and lower substrates, the liquid crystal layer containing liquid crystal molecules and the sealing material sealing the liquid crystal layer; and alignment control layers for controlling alignment of the liquid crystal molecules, one between the upper substrate and the liquid crystal layer and one between the lower substrate and the liquid crystal layer, wherein the upper and lower substrates are in direct contact with the sealing material, the alignment control layers contain a polymer having a structure derived from a polarized light-absorbing monomer having a polarized light-absorbing skeleton and at least two reactive functional groups, and the polarized light-absorbing skeleton includes a cinnamoyl skeleton. As described herein, the “polymer having a structure derived from a polarized light-absorbing monomer having a polarized light-absorbing skeleton and at least two reactive functional groups” means a polymer having a structure formed by a reaction of the at least two reactive functional groups. Examples thereof include a structure in which a reactive unsaturated bond as a reactive functional group is converted into a single bond and bonded to another monomer. In addition, the upper and lower substrates refer to both “upper substrate” and “lower substrate” in embodiments.

According to another aspect, the present invention may relate to a method for producing a liquid crystal display device, including: step (1) of forming a liquid crystal layer containing liquid crystal molecules and a polarized light-absorbing monomer between a pair of substrates bonded by a sealing material; step (2) of forming layers, one between the liquid crystal layer and one substrate and one between the liquid crystal layer and the other substrate, by irradiating the liquid crystal layer with polarized light to dimerize the polarized light-absorbing monomer and phase-separate the resulting dimer from the liquid crystal layer; and step (3) of forming alignment control layers for controlling alignment of the liquid crystal molecules by irradiating the liquid crystal layer with polarized light, with the temperature of the liquid crystal layer set to T_{N-I} or higher, where T_{N-I} indicates the phase transition temperature between a nematic phase and an isotropic phase of the liquid crystal molecules contained in the liquid crystal layer, wherein the polarized light-absorbing monomer has a polarized light-absorbing skeleton and at least two reactive functional groups, and the polarized light-absorbing skeleton includes a cinnamoyl skeleton.

### Advantageous Effects of Invention

In the liquid crystal display device of the present invention, the sealing material is prevented from being easily peeled from the upper and lower substrates even when the device has a narrow frame, and the alignment control layers are stable. The present invention can also achieve a horizontal alignment mode liquid crystal display device. The method for producing a liquid crystal display device of the present invention enables easy production of the liquid crystal display device of the present invention, and is suitable for industrial mass production of the liquid crystal display devices of the present invention.

### BRIEF DESCRIPTION OF DRAWINGS

FIG. 1 is a schematic cross-sectional view of a liquid crystal display device of Embodiment 1.

FIG. 2 is a schematic plan view of an exemplary pixel structure of an IPS mode liquid crystal display device.

FIG. 3 is a schematic cross-sectional view of a cross section taken along line A1-A2 in FIG. 2.

FIG. 4 is a schematic cross-sectional view of a cross section taken along line B1-B2 in FIG. 2.

FIG. 5 is a schematic plan view of an exemplary pixel structure of an FFS mode liquid crystal display device.

FIG. 6 is a schematic cross-sectional view of an exemplary FFS mode liquid crystal display device.

FIG. 7 is a schematic cross-sectional view of a liquid crystal display device of Embodiment 2.

FIG. 8 is a schematic cross-sectional view of a liquid crystal display device of Embodiment 3.

FIG. 9 is a schematic cross-sectional view of an exemplary conventional liquid crystal panel.

FIG. 10 is a schematic cross-sectional view of an exemplary conventional liquid crystal panel.

FIG. 11 is a schematic cross-sectional view of an exemplary conventional liquid crystal panel.

### DESCRIPTION OF EMBODIMENTS

The present invention is described in more detail in the following embodiments with reference to the drawings, but is not limited to these embodiments. The features of each embodiment may be appropriately combined or modified without departing from the gist of the present invention.

As used herein, the polarized light-absorbing monomer means a monomer having a polarized light-absorbing functional group in the molecule. The polarized light-absorbing monomer according to the present invention has the following properties because of the presence of a cinnamoyl skeleton therein. Specifically, the polarized light-absorbing monomer dissolves in the liquid crystal and is phase-separated from a liquid crystal layer when dimerized as the liquid crystal layer is irradiated with polarized ultraviolet light, and such a dimer formed under specific conditions deposits on the substrates. The specific conditions may include, for example, temperature changes and adsorption to inorganic compounds. In addition, the polarized light-absorbing functional group means a functional group that absorbs polarized light when irradiated with polarized light having a specific wavelength in an ultraviolet wavelength region and/or a visible light wavelength region.

In addition, a mode in which liquid crystal molecules are aligned in a direction substantially parallel to the main surfaces of the substrates when no voltage is applied is also referred to as the “horizontal alignment mode”. Being substantially parallel means that, for example, the pre-tilt angle of liquid crystal molecules is in the range of 0° to 5° from the main surfaces of the substrates. A mode in which liquid crystal molecules are aligned in a direction substantially perpendicular to the main surfaces of the substrates when no voltage is applied is also referred to as a vertical alignment mode. Being substantially perpendicular means that, for example, the pre-tilt angle of liquid crystal molecules is in the range of 85° to 90° from the main surfaces of the substrates. The room temperature is a temperature in the range of 15° C. to 30° C. The pre-tilt angle is measured by a crystal rotation method using a device (model number: OMS-AF2) available from Chuo Seiki Kabushiki Kaisha.

The following embodiments mainly describe a case where a horizontal alignment mode is achieved, but the present invention is also applicable to a case where a vertical alignment mode is achieved.

### Embodiment 1

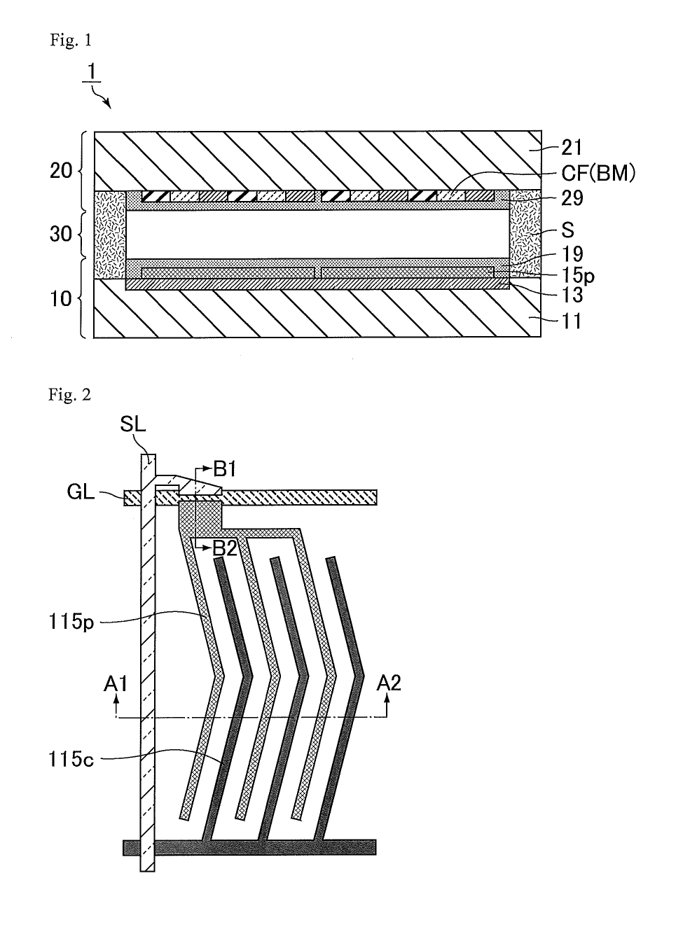

FIG. 1 is a schematic cross-sectional view of a liquid crystal display device of Embodiment 1. As illustrated in FIG. 1, a liquid crystal display device 1 includes a lower substrate 10, an upper substrate 20 facing the lower substrate 10, and a liquid crystal layer 30 and a sealing material S disposed between the substrates, and alignment control layers 19 and 29. The alignment control layer 19 is disposed between a glass substrate 11 of the lower substrate 10 and the liquid crystal layer 30. The alignment control layer 29 is disposed between a glass substrate 21 of the upper substrate 20 and the liquid crystal layer 30. The sealing material S is in direct contact with the glass substrate 11 of the lower substrate 10 and the glass substrate 21 of the upper substrate 20 without the alignment control layers 19 and 29 therebetween, respectively. The sealing material being in direct contact with the substrates means that the sealing material is in direct contact with glass substrates on the substrates, a TFT array, and/or color filters without alignment control layers therebetween. The liquid crystal display device may further include a pair of polarizing plates, one on the lower substrate 10 and one on the upper substrate 20, on the sides opposite to the liquid crystal layer 30.

The lower substrate 10 includes the glass substrate 11 as a supporting substrate and thin-film transistor elements (a TFT array substrate 13) suitably disposed on the glass substrate 11. The lower substrate 10 also includes pixel electrodes 15p and a common electrode (not shown) on the same layer or different layers in some portions on an insulating film that covers the TFT array substrate 13. Here, the pixel electrodes and a common electrode being on the same layer or different layers means that the pixel electrodes and the common electrode are in contact with the same component (e.g., the liquid crystal layer 30 or the insulating film) on the liquid crystal layer 30 side and/or the side opposite to the liquid crystal layer 30 side of the pixel electrodes and the common electrode. Indium tin oxide (ITO) or indium zinc oxide (IZO) can be suitably used as a material of the pixel electrodes and the common electrode. The upper substrate 20 does not include electrodes but it includes the glass substrate 21 as a supporting substrate and components such as a color filter layer CF (optionally with a black matrix BM on the same layer) suitably disposed on the glass substrate 21. In addition, the lower substrate 10 and the upper substrate 20 do not include conventional alignment films (e.g., the alignment films 717 and 727 in FIG. 9).

Unlike conventional liquid crystal display devices, the liquid crystal display device of Embodiment 1 includes substantially no portions where the alignment films adhere to the sealing material, and the sealing material is in direct contact with the substrates. Thus, it is possible to increase the adhesion strength of the sealing material to the substrate, resulting in a liquid crystal display device in which the sealing material is not easily peeled from the upper and lower substrates even when the device has a narrow frame. In addition, in the liquid crystal display device of Embodiment 1, the alignment control layers are not exposed to the outside environment, thus preventing a situation where moisture or the like enters from the edge of the alignment films exposed to the outside environment.

The alignment control layers 19 and 29 control the alignment of the liquid crystal molecules, and are formed as the polarized light-absorbing monomer having a polarized light-absorbing skeleton and at least two reactive functional groups, which has been added to the liquid crystal layer 30, is phase-separated from the liquid crystal layer 30 and polymerized. The horizontal alignment mode can be achieved with the alignment control layers 19 and 29.

The polarized light-absorbing monomer (hereinafter also simply referred to as the “monomer”) is required to be soluble in the liquid crystal.

The solubility of the monomer in the liquid crystal largely depends on the structure of a core portion (central portion). Monomers commonly used in photo-alignment films have a photoreactive group in the core portion, and their alignment is induced by a photoreaction. Examples of the photoreactive group include azobenzene groups that induce molecular alignment by polarized photoreaction, and photo-crosslinkable groups such as a cinnamic acid group, a chalcone group, a coumarin group, and anthracene group. However, monomers having an azo-based photo-functional group hardly dissolve in the liquid crystal. Among materials that induce dimerization, anthracene-based materials have low solubility in the liquid crystal, and only an amount of about 0.1% by mass or less dissolves in the liquid crystal. In contrast, materials having a cinnamoyl skeleton (—C₆H₅—CH═CH—CO—) are highly compatible with the liquid crystal.

Among compounds having a cinnamoyl skeleton, cinnamic acid represented by the following formula has one benzene ring, and can be used as a monomer according to the present invention when two or more reactive functional groups are bonded to the benzene ring.

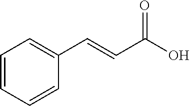 [SMILES: O=C(O)/C=C/c1ccccc1]

In particular, the chalcone skeleton has two benzene rings, and a monomer having a chalcone skeleton is easily rendered multifunctional. When the monomer is a bifunctional monomer having a chalcone skeleton, preferably, one or more reactive functional groups are bonded to each of the two benzene rings of the chalcone skeleton.

The monomer according to the present invention has a polarized light-absorbing skeleton and at least two reactive functional groups. Preferably, the core portion of the monomer is a polarized light-absorbing skeleton, and at least two reactive functional groups are directly bonded to the core portion.

### (Core Portion of Monomer)

The core portion of the monomer is preferably a polarized light-absorbing skeleton.

In order to form the alignment control layers that easily align the liquid crystal molecules by polarized light, the polarized light-absorbing skeleton as the core portion has a cinnamoyl skeleton. The polarized light-absorbing skeleton is preferably a chalcone skeleton. The benzene rings of the chalcone skeleton provide a rigid structure to the monomer.

It is essential that the core portion should dissolve in the liquid crystal, so that azo-based monomers used in photo-alignment films cannot be used as the core portion.

### (Spacer Portion)

The monomer forms the alignment control layers after polymerization. Having an ability to control the alignment of the liquid crystal molecules means that the alignment control layers strongly interact with the liquid crystal molecules, and when the liquid crystal molecules move under the effect of the electric field, stress is imparted to deform the alignment control layers. If a spacer (e.g., alkyl spacer) is present between the core portion and the reactive functional group and if the spacer is long, the alignment control layers will be easily deformed. In the present invention, preferably, the monomer does not include such a spacer. For example, preferably, the monomer has a structure in which the reactive functional group such as a (meth)acrylate group is directly bonded to a benzene ring. The (meth)acrylate group refers an acrylate group, a methacrylate group, or both of these groups.

### (Reactive Functional Group)

When the monomer has only one reactive functional group, polymerization of the monomer forms an easily deformable, linear polymer in which carbon-carbon bonds are one-dimensionally connected. The monomer having only one reactive functional group may reduce the voltage holding ratio of the liquid crystal.

In the present invention, as described above, since the polarized light-absorbing monomer has at least two reactive functional groups, polymerization of the polarized light-absorbing monomer results in the formation of a polymer having a network structure, making it possible to form a stable alignment control layers that are not highly soluble in the liquid crystal and that are not easily deformed by an external shock.

The reactive functional group is preferably one having a reactive unsaturated bond, more preferably a (meth)acrylate group, for example. For example, the monomer preferably has two (meth)acrylate groups.

Preferably, the monomer has a chalcone skeleton in which a reactive functional group such as methacrylate and/or acrylate is directly bonded to each benzene ring constituting the chalcone skeleton. A polymer formed from the monomer suitably forms alignment control layers. For example, 2-methyl acrylic acid 4-{3-[4-(2-methyl-acryloyloxy)-phenyl]-acryloyl}-phenyl ester represented by the following formula is particularly preferred. The monomer has a structure in which one methacrylate group is bonded to each of the two benzene rings constituting the chalcone skeleton.

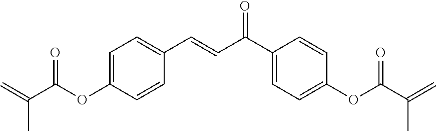 [SMILES: C=C(C)C(=O)Oc1ccc(/C=C/C(=O)c2ccc(OC(=O)C(=C)C)cc2)cc1]

The molecular structure having methacrylate and/or acrylate directly bonded to the benzene rings generates radicals due to Fries rearrangement upon irradiation with ultraviolet light. The radicals initiate polymerization, and a polymer layer is formed from a dimer deposited on the substrate surface as described later. The polymer that forms a polymer layer has a high molecular weight and a three-dimensional network structure. Thus, the polymer does not easily dissolve in the liquid crystal, remains stable as is the case with a conventional alignment film even when the liquid crystal panel is subjected to an external shock or the like, and can stably align the liquid crystal molecules.

Thus, the liquid crystal display device of Embodiment 1 includes stable alignment control layers formed on the substrates and eliminates an unstable state associated with alignment control layers including a low molecular material.

Next, a method for producing the liquid crystal display device of Embodiment 1 is described.

According to the method for producing the liquid crystal display device of Embodiment 1, preferably, a bifunctional monomer having a chalcone skeleton is used as a monomer in an amount of about 0.1 to 10% by mass in the entire liquid crystal mixture (100% by mass) constituting the liquid crystal layer. If the amount is less than 0.1% by mass, the alignment control layer may not be formed on the entire interface between the liquid crystal layer and each substrate, failing to sufficiently control the alignment of the liquid crystal molecules. If the amount is more than 10% by mass, the polarized light-absorbing monomer will highly likely remain in the liquid crystal layer after the post-process, which may affect the performance such as reliability. For example, the monomer may precipitate, impairing the display performance of the liquid crystal panel.

The amount is preferably 0.3% by mass or more, more preferably 1% by mass or more. Meanwhile, the amount is preferably 5% by mass or less.

With regard to the substrates, as is the case with conventional liquid crystal panels, one substrate may include color filters, and the other substrate may have a structure in which the potential of the pixel electrodes can be controlled by switching elements such as TFTs. However, unlike conventional methods for producing liquid crystal panels, alignment films are not formed on the substrates.

After an agent for forming a sealing material is applied to one substrate, specifically to the outer periphery of a region corresponding to the liquid crystal panel, the substrate and the other substrate are bonded together such that they face each other. Thus, a pair of substrates is formed with a space sealed by the sealing material inside. The space sealed between the pair of substrates is rendered vacuum. Then, an inlet for injecting a liquid crystal mixture containing the monomer into the space is dipped in the liquid crystal mixture to inject the liquid crystal mixture into the space.

Instead of injecting the liquid crystal mixture as described above, the liquid crystal and the monomer may be added dropwise to one substrate, and then the substrate may be bonded to the other substrate in a vacuum chamber.

The sealing material may be one that is cured by heat or ultraviolet light, or by both heat and ultraviolet light.

After injection (or dropwise addition) of the liquid crystal, the liquid crystal layer is irradiated with polarized ultraviolet light while the temperature of the liquid crystal layer is in the range of room temperature (e.g., 20° C.) to T_{N-I}+5° C. so as to dimerize the added monomer and phase-separate the resulting dimer from the liquid crystal layer to deposit the dimer on the substrates, thus forming dimer layers. The phase transition temperature (° C.) between the nematic phase and the isotropic phase of the liquid crystal molecules is indicated by T_{N-I} (also referred to as “NI point”). The dimer layers can function as alignment control layers that horizontally align the liquid crystal molecules in a predetermined direction. Further, the dimer layers are irradiated with polarized ultraviolet light to polymerize the dimer to form alignment control layers. While the liquid crystal is heated to the isotropic phase (i.e., the liquid crystal is heated to a temperature equal to or higher than the phase transition temperature T_{N-I} between the nematic phase and the isotropic phase of the liquid crystal molecules) so that the interaction between the dimer layers and the liquid crystal molecules is reduced to allow the alignment control layers to easily perform alignment, the dimer layers are irradiated with polarized ultraviolet light. Polarized ultraviolet light is emitted in the direction from the lower substrate with no color filters to the upper substrate. Subsequently, as the temperature is lowered to room temperature, the liquid crystal molecules are aligned by the alignment control layers. The temperature of the liquid crystal layer when irradiating the dimer layers with polarized ultraviolet light is preferably T_{N-I} or higher of the liquid crystal material used. Meanwhile, the temperature is preferably T_{N-I}+5° C. or lower. Even if the temperature of the liquid crystal panel is increased in the range of T_{N-I} to T_{N-I}+5° C., the dimer layer will not dissolve in the liquid crystal. This is because a polymer having a network structure is formed in the dimer layer by irradiation with polarized ultraviolet light and such a polymer no longer dissolves in the liquid crystal layer.

The liquid crystal may be either one having positive anisotropy of dielectric constant or one negative anisotropy of dielectric constant. In addition, T_{N-I} of the liquid crystal molecules is not particularly limited, and the liquid crystal having any T_{N-I} can be used. Yet, since there are cases where the liquid crystal layer is heated to a temperature equal to or higher than T_{N-I} upon irradiation with polarized ultraviolet light, T_{N-I} of the liquid crystal molecules is preferably below the glass-transition temperature of the sealing material.

After formation of the polymer, the temperature of the liquid crystal panel is cooled to room temperature, and components such as a polarizing plate and a backlight are suitably disposed. As a result, a transverse electric field mode liquid crystal display device in which the liquid crystal molecules are aligned substantially parallel to the main surfaces of the lower substrate and the upper substrates when no voltage is applied can be obtained.

As described above, the liquid crystal display device of Embodiment 1 can be suitably used not only as a vertical alignment mode liquid crystal display device but also as a horizontal alignment mode liquid crystal display device. In the case of the horizontal alignment mode, modes such as the IPS mode and the FFS mode are the main streams. The liquid crystal display device of Embodiment 1 can achieve not only the IPS mode and the FFS mode but also an electrically controlled birefringence (ECB) mode. Hereafter, the electrode structure of a horizontal alignment mode liquid crystal display device is described with more detail.

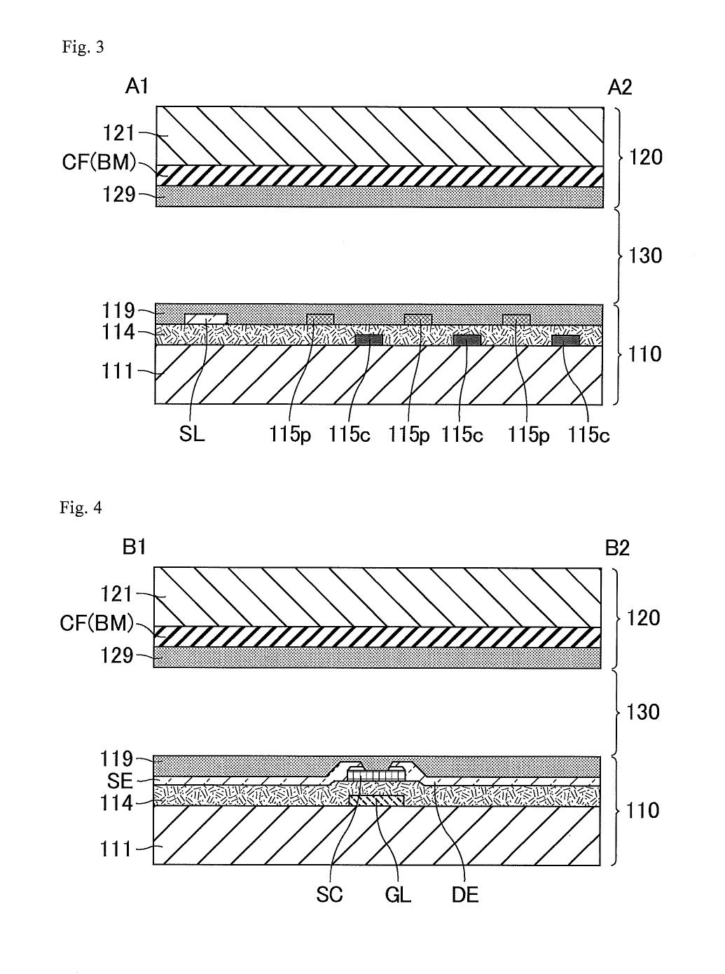

FIG. 2 is a schematic plan view of an exemplary pixel structure of an IPS mode liquid crystal display device. FIG. 3 is a schematic cross-sectional view of a cross section taken along line A1-A2 in FIG. 2. FIG. 4 is a schematic cross-sectional view of a cross section taken along line B1-B2 in FIG. 2.

The IPS mode liquid crystal display device shown in FIG. 2 includes a source bus line SL and a gate bus line GL on the lower substrate, and pixel electrodes 115p and common electrode 115c are disposed on different layers. The pixel electrodes and the common electrode may be disposed on the same layer instead of different layers. The gate bus line GL and the common electrode 115c are disposed on the same layer. The pixel electrodes 115p and the common electrode 115c are patterned. In FIG. 2, these electrodes form a pair of comb-teeth electrodes. As shown in FIG. 3, the IPS mode liquid crystal display device includes a lower substrate 110, an upper substrate 120 facing the lower substrate 110, and a liquid crystal layer 130 disposed between the substrates. The lower substrate 110 includes a glass substrate 111 and an alignment control layer 119. The upper substrate 120 includes a glass substrate 121, a color filter layer CF, and an alignment control layer 129. The pixel electrodes 115p and the common electrode 115c are disposed on different layers. In addition, as shown in FIG. 4, the IPS mode liquid crystal display device includes a source electrode SE, a drain electrode DE, and a semiconductor layer SC.

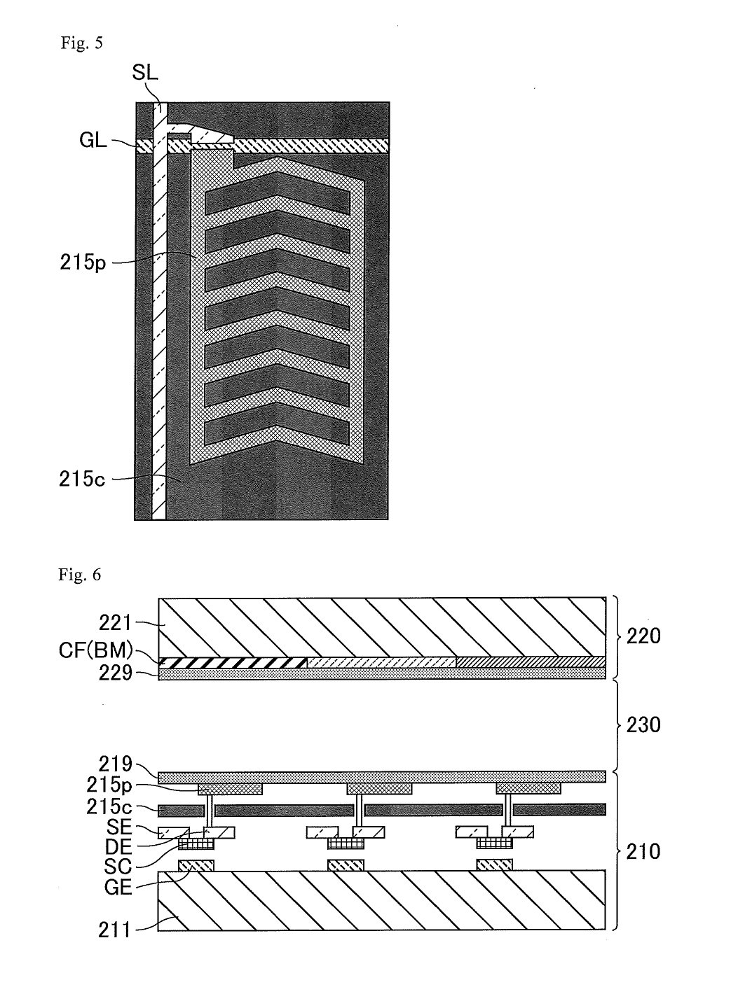

FIG. 5 is a schematic plan view of an exemplary pixel structure of an FFS mode liquid crystal display device. FIG. 6 is a schematic cross-sectional view of an exemplary FFS mode liquid crystal display device. As shown in FIG. 5 and FIG. 6, the FFS mode liquid crystal display device includes a lower substrate 210, an upper substrate 220 facing the lower substrate 210, and a liquid crystal layer 230 disposed between the substrates. The lower substrate 210 includes a glass substrate 211, a gate electrode GE, a semiconductor layer SC, a drain electrode DE, a source electrode SE, a common electrode 215c, pixel electrodes 215p, and an alignment control layer 219. The upper substrate 220 includes a glass substrate 221, a color filter layer CF, and an alignment control layer 229. A substrate including pixel electrodes and a common electrode disposed on different layers may be used as the lower substrate 210 to achieve the FFS mode. In such a case, an insulating film (not shown) is disposed between the pixel electrodes 215p and the common electrode 215c. The common electrode 215c may not be patterned.

### Embodiment 2

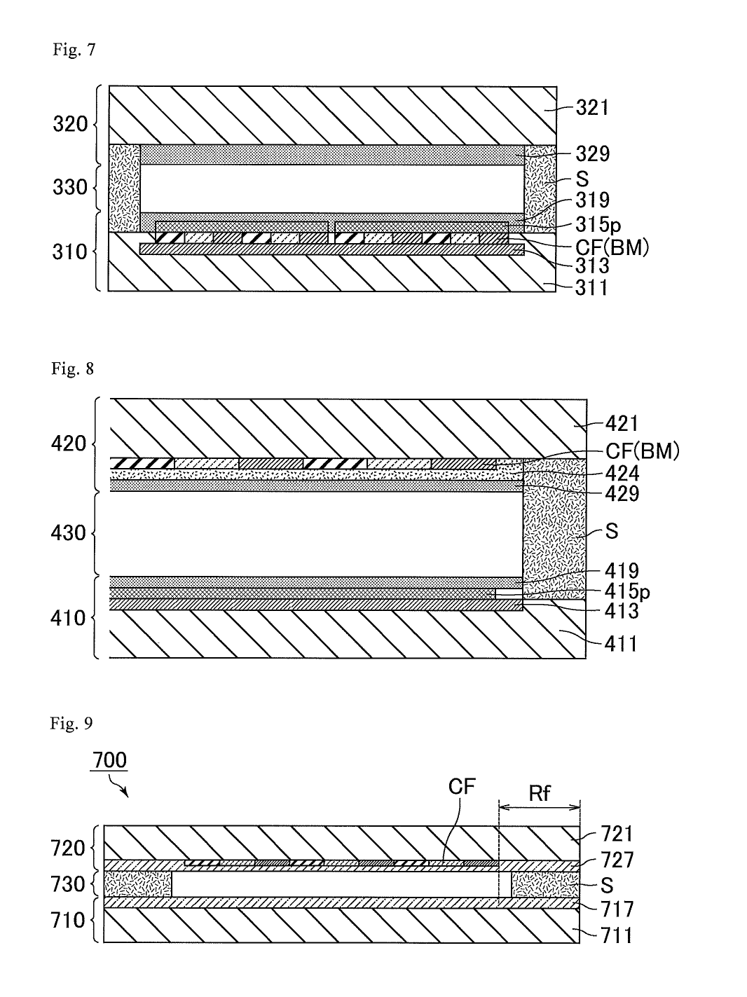

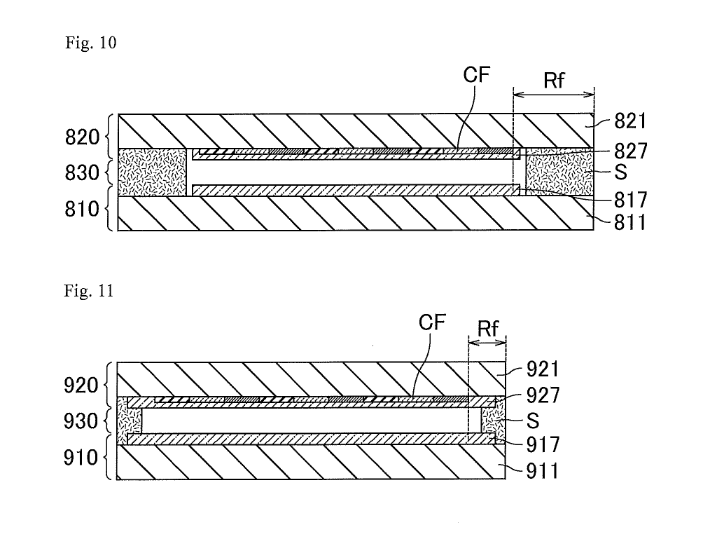

FIG. 7 is a schematic cross-sectional view of a liquid crystal display device of Embodiment 2.

The liquid crystal display device according to Embodiment 1 includes color filters and a black matrix disposed on the upper substrate. The color filters hardly transmit ultraviolet light, and the black matrix also does not transmit ultraviolet light. Thus, ultraviolet light to polymerize the monomer is emitted in the direction from the lower substrate (array substrate) with no color filters to the upper substrate.

The lower substrate has many light-blocking regions due to metal conductive lines constituting the TFT array. Thus, polymerization of the monomer in the liquid crystal by irradiation with ultraviolet light takes time. In addition, since the light-blocking portions interfere with the formation of the alignment control layers, there may be a wide light-blocking region where the alignment control layers cannot be formed. If such a case occurs, the liquid crystal molecules in the display region (on the pixel electrodes) may cause alignment defect.

Thus, in Embodiment 2, color filters CF are disposed on a lower substrate 310. As shown in FIG. 7, the liquid crystal display device of Embodiment 2 includes the lower substrate 310, an upper substrate 320 facing the lower substrate 310, and a liquid crystal layer 330 disposed between the substrates. The lower substrate 310 and the upper substrate 320 include a glass substrate 311 and a glass substrate 321, respectively. Color filters CF are formed on a TFT array substrate 313 of the lower substrate 310, and pixel electrodes 315p are formed on the color filters CF.

The upper substrate 320 of Embodiment 2 does not include any structures that block ultraviolet light. Thus, ultraviolet light to polymerize the monomer in the liquid crystal can be efficiently emitted in the direction from the upper substrate 320 to the lower substrate. In addition, since there are no shaded portions, the alignment control layers can be easily formed on the entire substrates.

The liquid crystal display device and the production method thereof of Embodiment 2 are the same as in Embodiment 1, except that the color filters CF are disposed on the lower substrate 310 instead of the upper substrate 320 and ultraviolet light to polymerize the monomer in the liquid crystal is emitted in the direction from the upper substrate 320 to the lower substrate. Such a liquid crystal display device including the color filters disposed on the lower substrate 310 can also achieve not only the vertical alignment mode but also the horizontal alignment mode with alignment control layers 319 and 329.

### Embodiment 3

FIG. 8 is a schematic cross-sectional view of a liquid crystal display device of Embodiment 3.

In the liquid crystal display device of Embodiment 3, the color filters CF are coated with an overcoat in order to prevent passage of impurities from the color filters. Since the adhesion of the sealing material S to an overcoat 424 is lower than the adhesion of the sealing material directly attached to the substrates, the overcoat 424 should not be disposed under the sealing material S (e.g., see JP 2010-8534 A).

As shown in FIG. 8, the liquid crystal display device of Embodiment 3 includes a lower substrate 410, an upper substrate 420 facing the lower substrate 410, and a liquid crystal layer 430 disposed between the substrates. The lower substrate 410 includes a glass substrate 411, a TFT array substrate 413, pixel electrodes 415p, and an alignment control layer 419. The upper substrate 420 includes a glass substrate 421, a color filter layer CF, the overcoat 424, and an alignment control layer 429. The liquid crystal display device of Embodiment 3 is the same as the liquid crystal display device of Embodiment 1, except that the overcoat 424 is disposed on the color filters CF. The liquid crystal display device of Embodiment 3 is effective in preventing passage of impurities from the color filters and ensuring the adhesion strength of sealing when the frame is made narrow.

It is possible to produce a vertical alignment mode (e.g., VA, vertical ECB, or vertical TN mode) liquid crystal display device using any of the liquid crystal display devices of the embodiments described above. Also in such a liquid crystal display device, the sealing material can be in direct contact with the upper substrate and the lower substrate, without conventional alignment films disposed between the sealing material and the upper and lower substrates. Thus, it is possible to produce a liquid crystal display device in which the sealing material is not easily peeled from the upper and lower substrates even when the device has a narrow frame.

### Comparative Embodiment 1

Azobenzene-based materials are widely known materials for use in photo-alignment films (e.g., K. Ichimura, Y. Suzuki, and T. Seki, Langmuir, 4. 1214 (1988)).

In the case where a multifunctional monomer is dissolved in the liquid crystal to be photopolymerized so as to form alignment control layers and the alignment control layers are used to align the liquid crystal as in Embodiment 1 described above, a compound represented by the following formula may be suggested, for example.

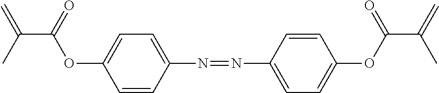 [SMILES: C=C(C)C(=O)Oc1ccc(N=Nc2ccc(OC(=O)C(=C)C)cc2)cc1]

The molecular size is preferably smaller for dissolution in the liquid crystal. The alkyl spacer portion between the core portion and the reactive functional group is preferably shorter (or absent) to prevent the polymerized polymer from being deformed by stress. Thus, the molecule has a structure including only one azobenzene in which a methacrylate group is directly bonded to each benzene ring constituting the azobenzene.

Attempts were made to dissolve the compound in the liquid crystal, but only less than 0.05% by mass of the compound dissolved in the entire liquid crystal layer. Thus, the compound could not be used to align the liquid crystal molecules.

### Additional Remarks

Examples of preferred aspects of the liquid crystal display device of the present invention are listed below. These examples may be appropriately combined without departing from the gist of the present invention.

In the present invention, the pair of substrates is in direct contact with the sealing material without an alignment film therebetween. The pair of substrates does not include conventional alignment films. Examples of components constituting the surface layer of each substrate which is in direct contact with the sealing material include supporting substrates (e.g., glass substrates), electrodes, and an insulating film. In view of enhancing the adhesion strength, a structure in which the glass substrates are in direct contact with the sealing material is preferred.

The polarized light-absorbing skeleton is preferably a chalcone skeleton.

Preferably, the reactive functional group contains a reactive unsaturated bond. More preferably, the reactive functional group contains a reactive double bond. The reactive double bond is further preferably a carbon-carbon double bond.

The reactive functional group is preferably a (meth)acrylate group.

The alignment control layers preferably align the liquid crystal molecules in a direction substantially parallel to the main surfaces of the upper and lower substrates when no voltage is applied. Thus, a horizontal alignment mode liquid crystal display device can be achieved. In one preferred embodiment of the present invention, the liquid crystal display device of the present invention is a horizontal alignment mode liquid crystal display device. The horizontal alignment mode may be, for example, an IPS mode, an FFS mode, or an ECB mode. The positive or negative anisotropy of dielectric constant of the liquid crystal can be selected to be best suited for each mode.

The alignment control layers may align the liquid crystal molecules in the direction substantially perpendicular to the main surfaces of the pair of substrates when no voltage is applied. Thus, a vertical alignment mode liquid crystal display device can be achieved. In another preferred embodiment of the present invention, the liquid crystal display device of the present invention is a vertical alignment mode liquid crystal display device. The vertical alignment mode maybe, for example, a vertical ECB mode, a 4-domain vertical ECB mode, a TBA (Transverse Bent Alignment) mode, a VA mode, a MVA (Multi-domain Vertical Alignment) mode, or a 4-domain vertical TN (Twisted Nematic) mode. The positive or negative anisotropy of dielectric constant of the liquid crystal can be selected to be best suited for each mode.

The polarized light-absorbing monomer may have a carboxy group, a hydroxyl group, or an amine group. Among these groups, the carboxy group is particularly preferred.

The liquid crystal material contained in the liquid crystal layer may have positive anisotropy of dielectric constant. In such a case, the major axis of each liquid crystal molecule is aligned along the line of electric force when voltage is applied, so that the alignment can be more easily controlled, further improving the high-speed response.

Examples of preferred aspects of the method for producing the liquid crystal display device of the present invention are listed below. These examples may be appropriately combined or modified without departing from the gist of the present invention.

The present invention may relate to a method for producing a liquid crystal display device, including: step (1) of forming a liquid crystal layer containing liquid crystal molecules and a polarized light-absorbing monomer between a pair of substrates bonded by a sealing material; step (2) of forming layers, one between the liquid crystal layer and one substrate and one between the liquid crystal layer and the other substrate, by irradiating the liquid crystal layer with polarized light to dimerize the polarized light-absorbing monomer and phase-separate the resulting dimer from the liquid crystal layer; and step (3) of forming alignment control layers for controlling alignment of the liquid crystal molecules by irradiating the liquid crystal layer with polarized light, with the temperature of the liquid crystal layer set to T_{N-I} or higher, where T_{N-I} indicates the phase transition temperature between a nematic phase and an isotropic phase of the liquid crystal molecules contained in the liquid crystal layer, wherein the polarized light-absorbing monomer has a polarized light-absorbing skeleton and at least two reactive functional groups, and the polarized light-absorbing skeleton includes a cinnamoyl skeleton.

In the present invention, the polarized light for irradiation in step (3) is preferably polarized ultraviolet light, particularly preferably linearly polarized ultraviolet light. Irradiation conditions of the polarized light can be appropriately set according to the composition of the polarized light-absorbing monomer.

In step (3), the liquid crystal layer may be irradiated with polarized light with the temperature of the layer set in the range of T_{N-I} to T_{N-I}+5° C.

Steps (1) to (3) may be performed at a constant temperature without changing the temperature of the liquid crystal layer. For example, the temperature of the liquid crystal layer in steps (1) to (3) is preferably constant in the range of T_{N-I} to T_{N-I}+5° C. without changing. This enables easy production of the liquid crystal display device of the present invention.

Step (1) may be performed with the temperature of the liquid crystal layer set to T_{N-I} or higher, and step (2) may be performed with the temperature of the liquid crystal layer lowered from T_{N-I} or higher to below T_{N-I}. This enables suitable formation of the alignment control layers owing to the effect that causes the polarized light-absorbing monomer to dissolve in the liquid crystal material at a temperature of T_{N-I} or higher and to phase-separate from the liquid crystal layer at a temperature below T_{N-I}.

Step (2) may be performed with the polarized light-absorbing monomer being adsorbed to an inorganic compound constituting the surface layer of each substrate of the pair. This enables suitable formation of the alignment control layers owing to the effect that causes the polarized light-absorbing monomer to be adsorbed to the inorganic compound.

### REFERENCE SIGNS LIST

10, 110, 210, 310, 410, 710, 810, 910: lower substrate
11, 21, 111, 121, 211, 221, 311, 321, 411, 421, 711, 721, 811, 821, 911, 921: glass substrate
13, 313, 413: TFT array substrate
15p, 115p, 215p, 315p, 415p: pixel electrode
15c, 115c, 215c, 315c: common electrode
19, 29, 119, 129, 219, 229, 319, 329, 419, 429: alignment control layer
20, 120, 220, 320, 420, 720, 820, 920: upper substrate
30, 130, 230, 330, 430, 730, 830, 930: liquid crystal layer
424: overcoat
700: liquid crystal display device
717, 727, 817, 827, 917, 927: alignment film
BM: black matrix
CF: color filter layer
DE: drain electrode
GE: gate electrode
GL: gate bus line
S: sealing material
SC: semiconductor layer
SE: source electrode
SL: source bus line
Rf: frame region

1. A liquid crystal display device comprising:
upper and lower substrates;
a liquid crystal layer and a sealing material between the upper and lower substrates, the liquid crystal layer containing liquid crystal molecules and the sealing material sealing the liquid crystal layer; and
alignment control layers for controlling alignment of the liquid crystal molecules, one between the upper substrate and the liquid crystal layer and one between the lower substrate and the liquid crystal layer,
wherein the upper and lower substrates are in direct contact with the sealing material,
the alignment control layers contain a polymer having a structure derived from a polarized light-absorbing monomer having a polarized light-absorbing skeleton and at least two reactive functional groups, and
the polarized light-absorbing skeleton includes a cinnamoyl skeleton.

2. The liquid crystal display device according to claim 1,
wherein the polarized light-absorbing skeleton is a chalcone skeleton.

3. The liquid crystal display device according to claim 1,
wherein the reactive functional group is a (meth)acrylate group.

4. The liquid crystal display device according to claim 3,
wherein the monomer has a structure in which the (meth)acrylate group is directly bonded to a benzene ring.

5. The liquid crystal display device according to claim 1,
wherein the alignment control layers align the liquid crystal molecules in a direction substantially parallel to main surfaces of the upper and lower substrates when no voltage is applied.

6. A method for producing a liquid crystal display device, comprising:
step (1) of forming a liquid crystal layer containing liquid crystal molecules and a polarized light-absorbing monomer between a pair of substrates bonded by a sealing material;
step (2) of forming layers, one between the liquid crystal layer and one substrate and one between the liquid crystal layer and the other substrate, by irradiating the liquid crystal layer with polarized light to dimerize the polarized light-absorbing monomer and phase-separate the resulting dimer from the liquid crystal layer; and
step (3) of forming alignment control layers for controlling alignment of the liquid crystal molecules by irradiating the liquid crystal layer with polarized light, with the temperature of the liquid crystal layer set to T_{N-I} or higher, where T_{N-I} indicates the phase transition temperature between a nematic phase and an isotropic phase of the liquid crystal molecules contained in the liquid crystal layer,
wherein the polarized light-absorbing monomer has a polarized light-absorbing skeleton and at least two reactive functional groups, and
the polarized light-absorbing skeleton includes a cinnamoyl skeleton.
